(19) United States
(12) Patent Application Publication
(10) Pub. No.: US 2007/0136642 A1
(43) Pub. Date: Jun. 14, 2007

(54) Conditional access to store content using non-standard media

(76) Inventor: Wolfgang Eberdorfer, Vienna (AT)

Correspondence Address: PHILIPS INTELLECTUAL PROPERTY & STANDARDS, P.O. BOX 3001, BRIARCLIFF MANOR, NY, 10510, US

(21) Appl. No.: 10/558,714

(22) PCT Filed: May 28, 2004
(86) PCT No.: PCT/IB04/50802

§ 371 Date: Feb. 8, 2007

(30) Foreign Application Priority Data
Jun. 2, 2003 (EP) 03101589.4

(51) Int. Cl. G11C 29/00

(52) U.S. Cl. 714/770

(57) ABSTRACT

A data carrier with at least one data recording area (2, 6) in which data recording area data are stored in accordance with a predefined data recording standard, comprises at least one defective area (3, 7) in the data recording area (2, 6), which defective area is designed in such a way that it comes into conflict with at least one parameter of the predefined data recording standard, and further comprises at least one defect localization area (4, 8) containing position information on the position of the at least one defective area (3, 7) on the data carrier (1, 5).

The invention relates to a data carrier with at least one data recording area in which data recording area data are stored in accordance with a predefined data recording standard.

The invention further relates to a data playback method of reading data from a data carrier by scanning the data carrier with scanning means.

The invention further relates to a data playback device for reading data from a data carrier, wherein the data are stored in a data recording area of the data carrier in accordance with a predefined data recording standard.

One such data carrier, one such data playback method and one such data playback device are known from document WO 01/43123. This document reveals the idea of utilizing areas on a data carrier that are not used, in accordance with a data recording standard, for the purpose of storing additional identification information in these unused areas. To be more precise, this document describes a number of possibilities resulting from the fact that information is recorded with the write laser beam in the space between the tracks of an optical disc, such as a CD-RW, the so-called land. This information can be created in such a way that a visibly discernible pattern appears on the disc. This pattern could, for example, also be an image of a finger print, thereby assigning the data carrier to a user in a unique fashion.

A drawback that has become apparent in the prior art data carrier, data playback method and data playback device is that the identification information or the resulting pattern respectively, are only written in areas of the data carrier that are not used by definition as data recording areas in accordance with the data recording standard. The supposed advantage that through this measure the data carrier remains readable on all players in which the data recording standard is implemented is countered by the disadvantage that the production of pirate copies of any such data carrier are in no way impeded by the prior art measures. Whilst pirate copies of a data carrier of this nature would not possess the visibly discernible patterns or the identification information of the original data carrier, the pirate copy still remains fully usable because it still fulfils the data recording standard.

It is an object of the present invention to create a data carrier in accordance with the type specified in the first paragraph, a data playback method of the type specified in the second paragraph and a data playback device of the type specified in the third paragraph, in which the disadvantages mentioned above are avoided. In order to solve the above task, characteristic features in accordance with the invention have been included in a data carrier in accordance with the invention, as a result of which the data carrier in accordance with the invention can be characterized in the following way, namely:

A data carrier with at least one data recording area in which data recording area data are stored in accordance with a predefined data recording standard, and at least one defective area is embedded, which defective area is designed in such a way that it comes into conflict with at least one parameter of the predefined data recording standard, as well as with at least one defect localization area containing position information about the position of the at least one defect area on the data carrier.

In order to achieve the above object, characteristic features in accordance with the invention are included in a data playback method in accordance with the invention, so that the data playback method in accordance with the invention can be characterized in the following way, namely:

A data playback method of reading data from a data carrier by scanning the data carrier with scanning means, wherein the data are stored in a data recording area of the data carrier in accordance with a predefined data recording standard wherein at least one defective area is embedded in the data recording area, which defective area is designed in such a way that it comes into conflict with at least one parameter of the predefined data recording standard, wherein the conflict can preferably not be rectified by standard-compliant error-correction measures in accordance with the data recording standard, and wherein the data carrier has at least one defect localization area containing position information about the position of the at least one defect area on the data carrier comprising:

the localization of at least one defective area on the data carrier by reading the position information from the defect localization area

reading the data from the data recording area when the scanning means scan the data recording area conforming to the standard,

moving the scanning means to a data reading position adjacent to a defective area in the data recording area if the scanning means are in a defective area.

In order to achieve the above object, characteristic features in accordance with the invention are included in a data playback device in accordance with the invention, so that the data playback device in accordance with the invention can be characterized in the following way, namely:

A data playback device for reading data from a data carrier, wherein the data are stored in a data recording area of the data carrier in accordance with a predefined data recording standard, wherein at least one defective area is embedded in the data recording area, which defective area is designed in such a way that it comes into conflict with at least one parameter of the predefined data recording standard, wherein the conflict can preferably not be rectified by standard-compliant error-correction measures in accordance with the data recording standard, and wherein the data carrier has at least one defect localization area containing position information about the position of the at least one defective area on the data carrier comprising:

scanning means for scanning the data carrier for the purpose of reading the data from the data recording area and of reading the position information about the position of the defective area from the defect localization area,

scanning control means for controlling the scanning means,

switching means for switching the scanning means and/or the scanning control means between a standard data playback mode and a defective area control mode, depending on the position information about the position of the defective area.

The characteristic features in accordance with the invention serve to prevent both pirate copies of the data carrier in accordance with the invention being created using recording devices which conform to the data recording standard, as well as data being read from the data carrier using data playback devices which conform to the data recording standard. The data stored on the data carrier can thus be reliably safeguarded against unauthorized access. On the other hand, the measures in accordance with the invention can be implemented relatively simply by adapting existing manufacturing lines for data carriers and hardware and/or firmware for data playback devices. The data playback devices remain compatible with the data recording standard designated for the data carrier to be read, but they also offer the additional feature of the operability of a proprietary storage medium format. The invention is particularly advantageous, among other things, for games console manufacturers.

In accordance with the measures claimed in claim 2, the advantage is obtained that such data carriers can only be created in specially equipped manufacturing plants, thereby rendering commercial fraud through the production of pirate copies enormously difficult. It should be mentioned that such physical parameters may, for example, comprise the thickness, position, reflection capacity or transparency of the different layers of optical data carriers, or the track positions or dimensions of data tracks on the data carrier.

In accordance with the measures claimed in claim 3, the advantage is obtained on the other hand that manufacturing plants do not have to be especially re-equipped for the production of data carriers in accordance with the invention. As logical parameters can be changed more simply than physical parameters, it is essential to keep the critical, logical parameter values secret in this case and/or to implement their analysis in terms of hardware in adapted data playback devices.

In accordance with the measures claimed in claim 4, the advantage is obtained that the data access protection achieved through the invention in terms of the data on the data carrier in accordance with the invention does not occur with the error-correction means available in standard playback devices.

In accordance with the measures claimed in claim 5 and claim 13, the advantage is obtained on the other hand that the defect localization area can be placed on the data carrier without coming into conflict with the data recording standard.

In accordance with the measures claimed in claim 6 and claim 14, the advantage is obtained on the other hand that the data carrier offers very robust protection against damage, such as scratches.

In accordance with the measures claimed in claims 7, 8, 12, 15, 16 and 19, the advantage is obtained that each data carrier is identifiable, while identification can take place on different levels, such as the assignment of the data carrier to a series or to a specific manufacturer or user. The identification information can also contain a unique identification number, of course. The identification information can form a visible pattern on the data carrier, for example a picture or a finger print. In accordance with the measures claimed in claims 20 and 21, the identification information can also be used for extremely effective data access protection.

In accordance with the measures claimed in claim 9, existing data playback devices can be adapted in a relatively simple way for continuous data playback. These and other aspects of the invention are apparent from and will be elucidated with reference to the embodiments described hereinafter.

In the drawings:

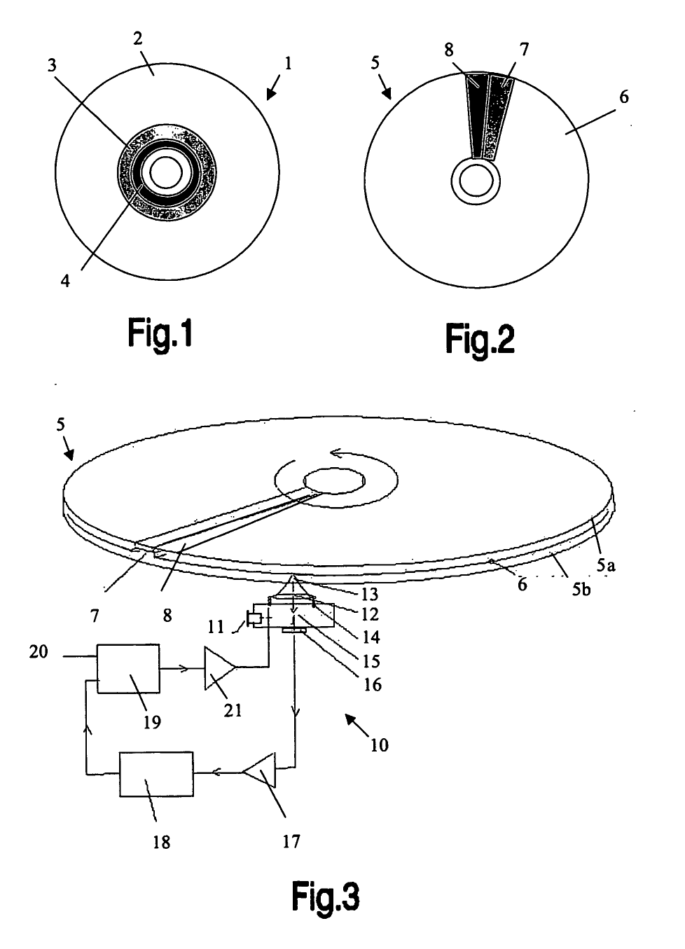

FIG. 1 shows a diagram of a top view of a data carrier in accordance with the invention.

FIG. 2 shows a diagram of a top view of another embodiment of a data carrier in accordance with the invention.

FIG. 3 shows a block diagram of scanning means for scanning an optical data carrier.

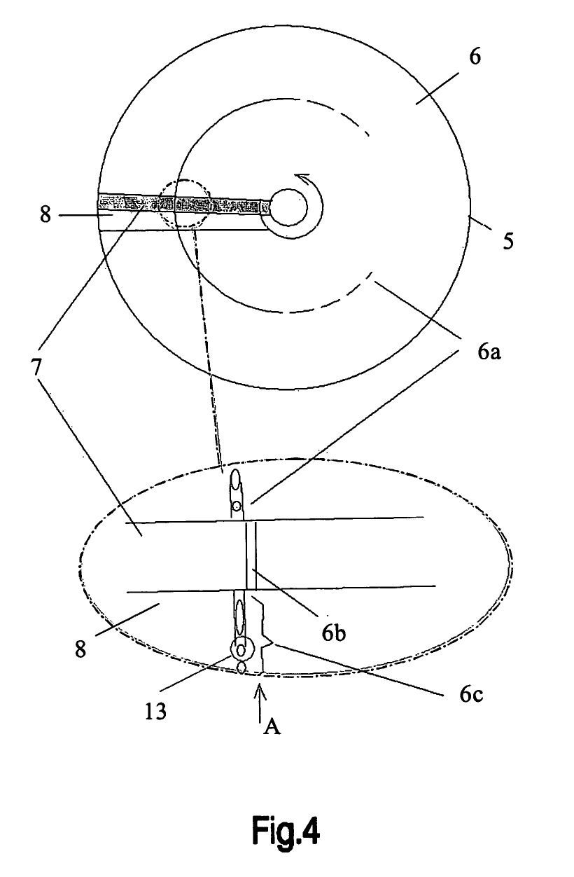

FIG. 4 shows a diagram of a top view and enlargement of another embodiment of an optical data carrier in accordance with the invention.

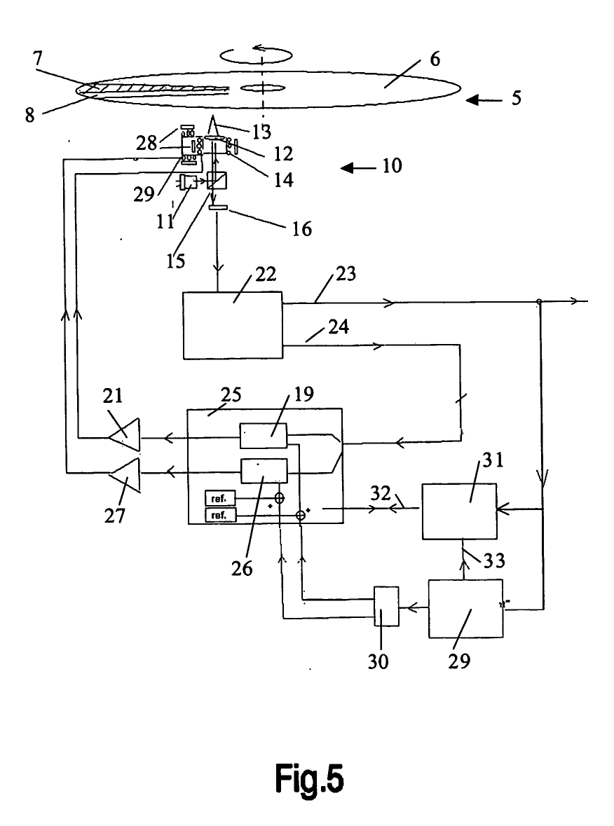

FIG. 5 shows a block diagram of a data playback device in accordance with the invention.

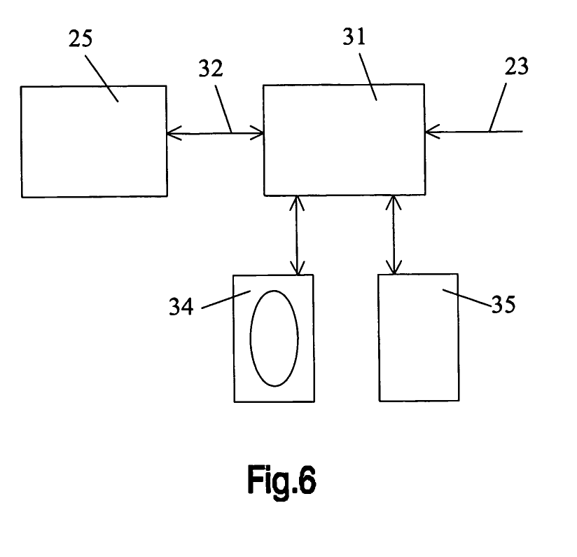

FIG. 6 shows a block diagram of an identification analysis circuit to complement the data playback device shown in FIG. 5

FIG. 1 shows a diagram of a top view of a data carrier 1 in accordance with the invention, which is designed as a disc-shaped, optical data carrier, e.g. as a CD, CD-ROM or DVD. The data carrier 1 possesses a ring-shaped data recording area 2 in which data is stored in accordance with a predefined data recording standard, e.g. the CD standard or DVD standard. In accordance with both the CD standard and the DVD standard, the data is stored in the data recording area in a data track which helically extends outwards from the inner edge of the data recording area. There is a concentric, ring-shaped defective area 3 on the inner edge of the data recording area 2, which defective area is designed in such a way that it comes into conflict with at least one parameter of the predefined data recording standard. It should be mentioned that the parameter which comes into conflict with the data recording standard may be a physical parameter, such as the refractive index of a polycarbonate top layer, the reflection capacity of a metallization level containing the data or the polarization level of a laser beam which is provided for scanning the data carrier. Such changes in the data carrier medium cause servo-circuits in a scanning means to cease to work properly. This may disrupt the focusing of a read laser beam or its guidance on the data track. It should also be mentioned that the parameter which comes into conflict with the data recording standard may be a logical parameter, and the conflict may comprise missing lead-in areas, missing tables of contents, missing or incorrect media tags or scanning means calibration details, etc. The predefined parameters may be of decisive significance in respect of the CD or DVD standard, for example, which means that, as a result of the conflict with the standard criteria, the CD or DVD may no longer be readable on standard drives. There is then a ring-shaped defect localization area 4, containing information about the position of the defective area 3 on the data carrier 1, along the inner edge of the data recording area 2. As regards the scanning of the data recording area by a scanning means, the defect localization area 4 is located before the data recording area 2.

FIG. 2 shows a diagram of a top view of another data carrier 5 in accordance with the invention, which is designed as a disc-shaped, optical data carrier, e.g. as a CD, CD-ROM, CD-RW, DVD or DVD+(−)(R)W. The data carrier 5 has a ring-shaped data recording area 6 in which data is stored in accordance with a predefined data recording standard, e.g. the CD standard or DVD standard. A sector-shaped or strip-shaped defective area 7, which is designed in such a way that it comes into conflict with at least one of the parameters of the predefined data recording standard, extends across the data carrier from the inside outwards, straight through the data recording area 6. It should be mentioned that the shape and position of the defective area in the data recording area is not restricted any further, and that there may also be several defective areas. In addition to the defective area 7, there is also a sector-shaped defect localization area 8, containing information about the position of the defective area 7 on the data carrier 5. As regards the scanning of the data recording area by a scanning means, the defect localization area 8 is located before the data recording area 7. Consequently, in the event of the CD or DVD standard, each data track winding first of all passes through the defect localization area 8 and then through the defective area 7 in which the data track conforming to the standard is interrupted. Data blocks are encoded into the sections of the data track windings in defect localization area 8, which data blocks are provided as position information and provide information about the nature and the position of the subsequent defective area, for example which specify a start position and an end position on the sections of data track windings, which extend through the defective areas and, due to the lack of conformity with the standard in these defective sections, cannot be scanned correctly by the scanning means. The errors caused by the defective areas in reading the data are so serious that, unlike scratches on the surface of the data medium, for example, they cannot be corrected by standard-compliant error detection and correction circuits in a standard playback device.

Defective areas 3 and 7 on data carriers 1 and 5 can, on the one hand, be designed to prevent data being read from the data recording areas 2 and 6 of the data carrier by containing illegal spaces or interference information. However, they may also contain additional identification information, which is not defined in the data recording standard that is used, which additional identification information facilitates a unique identification of the data carrier. For example, the identification information may be one or more of the following items, namely a serial number, a personal identification number for a manufacturer or user, a finger print an image of a user, a digital file, such as an image file or an encryption file, and others.

FIG. 3 shows a block diagram of a scanning means 10 for scanning an optical data carrier 5, which is designed as a DVD. In accordance with the DVD standard, a data recording area 6, which is designed as a reflecting metallization layer, is arranged between two transparent polycarbonate layers 5a, 5b, each of which is about 0.6 mm thick. The scanning means 10 for reading data from the data carrier 5 comprises a laser diode 11 whose emitted laser beam 13 is focused by a lens 12 and is directed to the data recording area 6. Focusing coils 14 are provided to adjust the lens 12. The laser beam 15, which is reflected from the data recording area 6, is detected by a photo detector 16 and converted into an electrical signal, which is amplified by a photo detector signal amplifier 17 and is then fed to a focusing error signal generator 18. The output signal which is supplied by the focusing error signal generator 18 is fed to a focusing PID controller 19 as an input signal, where it is compared with a reference and focus offset value 20. The focusing PID controller 19 supplies a control signal, which is amplified by a driver 21 and with which the focusing coils 14 are activated for re-adjusting the lens 12. The scanning means 10 correspond to the conventional scanning means used in standard drives.

In accordance with the invention, the data carrier 5 is designed with a strip or sector-shaped defective area 7, which, in this embodiment, is designed in such a way that the polycarbonate layer 5a, on whose inside surface the metallized data recording area 6 is applied, is executed more thinly in this area. This changes the focusing level to a degree that cannot be corrected by the control circuit with a PID controller 19 during the time when the focused laser beam 13 travels across the defective area 7. As a result, a standard playback device, in which the scanning means 10 are implemented, loses the focus on the level of the data recording area in this defective area, and data losses occur because the scanning means also still require a certain recovery time for re-focusing and to locate the correct data track whenever the laser beam 13 has already returned to the portion of the data carrier which conforms to the standard. It has been shown that it only takes a defective area 7 measuring approx. 2 to 6 mm in width to render the data carrier unreadable for standard drives. In order to ensure that the data carrier is not rendered entirely unusable by the defective area 7, there is a defect localization area 8 whose function is described in greater detail below.

FIG. 4 shows a diagram of a top view and enlargement of a variant of an optical data carrier 5 in accordance with the invention. The optical data carrier 5 comprises a ring-shaped data recording area 6 in which a spiral-shaped data track 6a extends from the inside outwards, whose data is characterized by raised and recessed areas along the track. The data track 6a is interrupted in each winding by a defective area 7 in which each section 6b of the data track is offset radially to the normal pattern. As a result, a laser beam 13 which is scanning the data track 6a loses the data track when it scans the defective area 7. The scanning direction is characterized by arrow A. There is a defect localization area 8 in the scanning direction before the defective area 7, in which one of the sections 6c of the data track contains data which data is provided as position information and provides information on the size and the position of the next misalignment of the section 6b of the data track in the defective area 7. However, the data playback device described below is required for interpreting this data in the section 6c of the data track correctly. In the case of conventional drives, such a data carrier would be rejected as unreadable.

FIG. 5 shows a block diagram of a data playback device in accordance with the invention. This data playback device is suitable for reading data from the data carriers shown in FIGS. 1 to 4 which, unlike data carriers conforming to the standard, are supplemented in accordance with the invention by a defective area and a defect localization area, which indicates the position of the defective area. The data playback device in accordance with the invention comprises scanning means 10, which may be of a conventional nature, as already explained on the basis of FIG. 3, i.e. scanning means with a laser diode 11, whose emitted laser beam 13 is focused by a lens 12 and is directed to the data recording area 6. Focusing coils 14 are provided to adjust the focus of the lens 12. The laser beam 15, which is reflected from the data recording area 6, is detected by a photo detector 16 and converted into an electrical signal, which is fed to a circuit block 22. The circuit block 22 provides for the amplification, filtering and other adaptation of the signal from the photo detector 16 and generates two output signal paths, namely a high-frequency signal path 23 on the one hand, in which the data read from the data carrier is assigned serial codes (i.e. both data which is read from the data recording area 6 and which is encoded in accordance with a predefined data recording standard and data which does not conform to the standard and which is read from the defect localization area 8 and, where appropriate, from the defective area 7), and, on the other hand, a low frequency path which comprises servo-error signals and suchlike for the re-adjustment of the servo circuits in the scanning means. The servo-error signals may describe focus errors and radial errors of the scanning laser beam.

The low-frequency signal path 24 is led to scanning control means 25 which contain the servo-circuits for controlling the scanning means 10. In particular, the scanning control means 25 comprise a focusing PID controller 19, which generates a control signal from the fed focusing error signal, which control signal is amplified by a driver 21, which drives the focusing coils 14 for re-adjusting the focus of the lens 12. Furthermore, the scanning control means 25 comprise a radial PID controller 26, which is responsible for tracking the laser beam, i.e. keeping the focused laser beam 13 on the spiral-shaped data track. The radial PID controller 26 receives a radial error signal from the low-frequency signal path 24 and, on the basis of this error signal, generates a control signal which is amplified in a driver 27 which drives a tracking coil 29, which interacts with magnets 28 to misalign the laser beam radially.

In order to read data from the data carrier 5 in accordance with the invention, in addition to the conventional scanning means 10 and scanning control means 25, there is also a switching means 29 which detects position information about the position of defective areas from the data on the high-frequency signal path 23, with the predefined data emanating from the defect localization area 8 on the data carrier 5. Based on this position information, the switching means 29 switches the scanning control means 25, and thereby indirectly the scanning means 10, between a standard data playback mode and a defective area control mode. It should be mentioned that position information about the position of defective areas may contain either their absolute position or their relative position on the data carrier or the data track. It should further be mentioned that the position information about the position can also be concluded implicitly from the data recording standard that is used. For example, it is known from the CD or DVD format that the data is stored on a helical data track, running from the inside outwards, in the form of raised and recessed areas, while the current rotating speed of the CD or DVD is known at all times, so that it can be stated in accordance with the invention for example that, following a predefined period of delay after a tag data block has occurred in the data track, a defect will occur rendering the reading of the data track in accordance with the predefined data recording standard impossible. The tag data block may also contain information about the length of the defect and/or about the nature of the measures that have to be taken in order to scan the defect for information or in order to overcome it successfully, at least.

In the embodiment of the data playback device in accordance with the invention shown in FIG. 5, the switching means detects the described tag data blocks in the data of the high-frequency signal path 23 and analyzes it, where the information contained in it, for example, could be that the defect occurring in x μs is a defect that is characterized by a radial misalignment of the data track by y μm inwards or outwards and/or which is characterized by a misalignment of the focusing level by z μm upwards or downwards. Provided with this information, the switching means 29 can, taking due account of any delay times in the control circuit and mechanical inertia on the part of the scanning means, switch the scanning control means 25 from the standard data playback mode to a defective area control mode at the determined switching time, by setting a changed reference value for tracking the laser beam 13 to the tracking PID controller 26, which is implemented in the scanning control means 25, via a digital/analog converter 30, which reference value leads to a corresponding radial misalignment of the tracking coil 29, and thus of the laser beam 13, and/or by setting a changed reference value for focusing the laser beam 13 to the focusing PID controller 19, which is implemented in the scanning control means 25, which reference value leads to a corresponding re-adjustment of focusing coil 14, and thus of the focusing level of the laser beam 13. The tag data blocks may further contain timing information 33 regarding the next or all defective areas, which is forwarded from the switching means 29 to a microcontroller 31, which stores this information in a buffer memory and, for its part, activates the scanning control means 25 via the control line 32 and the switching means 29, in accordance with this timing information.

The data carrier in accordance with the invention would not be readable without these measures in accordance with the invention in the data playback device because a defect of corresponding length, containing no data, or invalid or unreadable data, would cause data clock rate synchronization circuits in conventional CD or DVD drives to go out of step. On the other hand, the data playback device in accordance with the invention maintains downward compatibility with the CD or DVD standard and can thus read conventional CDs and DVDs (as well as write to them, where appropriate).

In order to ensure even better data protection on the data carrier in accordance with the invention, identification information can be encoded into the defective area which is read from the data carrier in advance and is analyzed in the playback device. According to the description of the data playback device in accordance with the invention, as shown in FIG. 5, the scanning means 10 can be switched over to a defective area control mode in which they can read information, which does not conform to the data recording standard for the data carrier, from the defective area. This identification information is transmitted via high-frequency signal path 23.

FIG. 6 shows a block diagram of an identification analysis circuit to complement the data playback device in accordance with the invention shown in FIG. 5. In the circuit in FIG. 6, the microcontroller 31 receives the high-frequency signal path 23 and filters identification information from this which is compared with a default value previously stored in a memory 35. In the embodiment shown here, a default value can also be received from a finger print scanner 34. The identification information is compared with the default value by the microcontroller 31 and, if the comparison does not conform to certain criteria, a stop signal is sent to the scanning control means 25 in order to prevent the further scanning of the data carrier. It should be mentioned that the default values can be written to the memory 35 by reading them from a reference CD.

1. A data carrier with at least one data recording area (2, 6) in which data recording areas (2, 6) data are stored in accordance with a predefined data recording standard, and at least one defective area (3, 7) is embedded, which defective area (3, 7) is designed in such a way that it comes into conflict with at least one parameter of the predefined data recording standard, as well as with at least one defect localization area (4, 8) containing position information about the position of the at least one defective area (3, 7) on the data carrier (1, 5).

2. A data carrier as claimed in claim 1, characterized in that the parameter of the data recording standard with which parameter the defective area (3, 7) comes into conflict defines a physical parameter of the data carrier.

3. A data carrier as claimed in claim 1, characterized in that the parameter of the data recording standard with which parameter the defective area (3, 7) comes into conflict is a logical parameter of the data recording standard.

4. A data carrier as claimed in claim 1, characterized in that the defective area (3, 7) is in conflict with the at least one parameter of the predefined data recording standard in such a way that the conflict cannot be rectified by standard-compliant error-correction measures in accordance with the data recording standard.

5. A data carrier as claimed in claim 1, characterized in that, in relation to data scanning means (10), the defect localization area (4) is located before the data recording area (2).

6. A data carrier as claimed in claim 1, characterized in that, in relation to data scanning means (10), there is a defect localization area (4, 8) located before each defective area (3, 7).

7. A data carrier as claimed in claim 1, characterized in that at least one defective area (3, 7) contains identification information.

8. A data carrier as claimed in claim 7, characterized in that the identification information comprises one or more of the following items, namely a serial number, a personal identification number, a finger print and a digital file, such as an image file.

9. A data carrier as claimed in claim 1, characterized in that the position information about the position of the at least one defective area (7) on the data carrier comprises a start position information and on end position information of each of the defective areas along a data track (6a) in the data recording area (6).

10. A data carrier as claimed in claim 1, which is an optical data carrier, such as a CD, a CD-ROM or a DVD.

11. A data playback method of reading data from a data carrier (1, 5) by scanning the data carrier with scanning means (10), wherein the data are stored in a data recording area (2, 6) of the data carrier in accordance with a predefined data recording standard, wherein at least one defective area (3, 7) is embedded in the data recording area, which defective area (3, 7) is designed in such a way that it comes into conflict with at least one parameter of the predefined data recording standard, wherein the conflict can preferably not be rectified by standard-compliant error-correction measures in accordance with the data recording standard, and wherein the data carrier has at least one defect localization area (4, 8) containing position information about the position of the at least one defective area (3, 7) on the data carrier, comprising:
the localization of at least one defective area (3, 7) on the data carrier by reading the position information from the defect localization area (4, 8),
reading the data from the data recording area (2, 6) when the scanning means (10) scan the data recording area conforming to the standard,
moving the scanning means (10) to a data reading position adjacent to a defective area (3, 7) in the data recording area (2, 6) if the scanning means are in a defective area.

12. A data playback method as claimed in claim 11, characterized in that moving the scanning means via a defective area comprises switching the scanning means to a non-standard scanning mode in which the scanning means receive signals from the defective area which do not conform to the data recording standard.

13. A data playback method as claimed in claim 11, characterized in that, in relation to the scanning means, the defect localization area (4, 8) is located before the data recording area (2, 6).

14. A data playback method as claimed in claim 11, characterized in that, in relation to the scanning means, there is a defect localization area (4, 8) located before each defective area (3, 7).

15. A data playback method as claimed in claim 12, characterized in that the signals received by the scanning means (10) from the defective area (3, 7) contain identification information.

16. A data playback method as claimed in claim 15, characterized in that the identification information comprises one or more of the following items, namely a serial number, a personal identification number, a finger print and a digital file, such as an image file.

17. A data playback method as claimed in claim 11, characterized in that the position information about the position of the at least one defective area (7) on the data carrier comprises a start position information and an end position information of each of the defective areas along a data track (6a) in the data recording area (6), and moving of the scanning means (10) is controlled on the basis of this position information.

18. A data playback device for reading data from a data carrier (1, 5), wherein the data are stored in a data recording area (2, 6) of the data carrier in accordance with a predefined data recording standard, wherein at least one defective area (3, 7) is embedded in the data recording area (2, 6), which defective area is designed in such a way that it comes into conflict with at least one parameter of the predefined data recording standard, wherein the conflict can preferably not be rectified by standard-compliant error-correction measures in accordance with the data recording standard, and wherein the data carrier has at least one defect localization area (4, 8) containing position information about the position of the at least one defective area (3, 7) on the data carrier comprising:
scanning means (10) for scanning the data carrier for the purpose of reading the data from the data recording area (2, 6) and of reading the position information about the position of the defective area (3, 7) from the defect localization area (4, 8),
scanning control means (25) for controlling the scanning means (10),
switching means (29) for switching the scanning means (10) and/or the scanning control means (25) between a standard data playback mode and a defective area control mode, depending on the position information about the position of the defective area.

19. A data playback device as claimed in claim 18, characterized in that the scanning means (10) are designed to enable reading of identification information from the defective area (3, 7) in the defective area control mode.

20. A data playback device as claimed in claim 19, characterized in that comparing means (31) for comparing the identification information with default values are provided.

21. A data playback device as claimed in claim 20, characterized in that the comparing means (31) are designed to prevent reading of the data from the data carrier if the identification information does not match the default values.
